(19) United States
(12) Patent Application Publication
(10) Pub. No.: US 2009/0035669 A1
(43) Pub. Date: Feb. 5, 2009

(54) WORK POSITION INFORMATION OBTAINING METHOD AND APPARATUS

(75) Inventors: Hiroshi Uemura, Kanagawa-ken (JP); Kazuhiro Terada, Kanagawa-ken (JP); Takashi Fukui, Kanagawa-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Minato-ku, Tokyo (JP)

(21) Appl. No.: 11/912,580

(22) PCT Filed: Apr. 26, 2006
(86) PCT No.: PCT/JP2006/308704

§ 371 Date: Oct. 25, 2007

(30) Foreign Application Priority Data
Apr. 28, 2005 (JP) 2005-133591

(51) Int. Cl. G03F 9/00; G03B 27/42

(52) U.S. Cl. 430/22; 355/53

(57) ABSTRACT

A work position information obtaining apparatus capable of obtaining a position of a work with respect to a table with high accuracy. Moving a table with a work placed thereon relative to an imaging section. Obtaining work position information representing a position of the work with respect to the table based on imaged information obtained by imaging table and work reference marks by the imaging section and moving direction positions of the table at the time of imaging the table and work reference marks. Obtaining the positional deviations of the table at the time of imaging the table and work reference marks, with reference to a positional deviation of the table obtained in advance in association with each of the moving direction positions of the table. Then, eliminating an error included in the work position information arising from the difference between each imaged positional deviation.

### CROSS REFERENCE TO RELATED APPLICATIONS

This application is a National Stage of International Application No. PCT/JP2006/308704 filed on Apr. 26, 2006, claiming priority based on Japanese Patent Application No. 2005-133591, filed Apr. 28, 2005, the contents of all of which are incorporated herein by reference in their entirety.

### TECHNICAL FIELD

The present invention relates to a work position information obtaining method and apparatus. More specifically, the present invention relates to a work position information obtaining method and apparatus for obtaining a position of a work with respect to a table on which the work is placed and moved.

### BACKGROUND ART

As an example of image plotting systems for plotting an image on a work, a system having an image plotting head which includes a DMD (digital micromirror device) for outputting an image plotting beam is known as described, for example, in Japanese Unexamined Patent Publication No. 2004-001244. Among such type of image plotting systems, for example, a system in which an image plotting table with a work of a photosensitive material placed thereon is moved unidirectionally under the image plotting head, and while the table is moved, an image pattern is exposed on the work placed on the table by irradiating an image plotting beam outputted from the image plotting head on the work is known.

The work may be placed manually on the table, so that the position of the work with respect to the table is not fixed. A method for plotting an image pattern on a correct position of the work by an image plotting beam outputted from the image plotting head is known, in which a work position with respect to the table is obtained in advance, and the image pattern is plotted on the work by compensating for a deviation from the designed position.

In order to obtain the position of the work with respect to the table, for example, a method may be used in which the position of the work with respect to the table is obtained based on image information obtained by sequentially imaging portions of the table being moved with respect to a base of a system with an imaging means, attached to the base, for imaging over the surface of the table.

That is, the position of the work with respect to the table may be obtained by first imaging a table reference mark provided on the table being moved with respect to the base and then a work reference mark provided on the work placed on the table with the imaging means, and using the positions of the table and work reference marks within the field of the imaging means and a moving distance of the table during the time period from the time when the table reference mark is imaged to the time when the work reference mark is imaged.

In the mean time, there exists a demand for the image plotting systems that circuit patterns requiring high image plotting accuracy, such as multilayer circuitry be plotted. In order to plot an image pattern on a work placed on a table with such high positional accuracy, it is necessary to obtain the position of the work with respect to the table more accurately.

The present invention has been developed in view of the circumstances described above, and it is an object of the present invention to provide a work position information obtaining method and apparatus capable of obtaining a position of a work on a table more accurately.

### DISCLOSURE OF THE INVENTION

A first work position information obtaining method of the present invention is a method including the steps of:

moving a table with a work placed thereon relative to an imaging means for imaging over the surface of the table;

obtaining imaged table information and imaged work information by imaging a table reference mark provided on the table being moved and a work reference mark provided on the work placed on the table, and obtaining moving direction position information representing moving direction positions of the table when the table reference mark and work reference mark are imaged; and

obtaining work position information representing a position of the work with respect to the table based on the imaged table information, imaged work information, and moving direction position information, wherein:

imaged positional deviation information representing an imaged positional deviation, which indicates displacement of the table that occurs when the table is moved relative to the imaging means, in association with each of the moving direction positions of the table is obtained in advance; and

an error included in the work position information arising from the difference between each imaged positional deviation is eliminated using the imaged positional deviation corresponding to the moving direction position of the table at the time of imaging the table reference mark obtained from the imaged positional deviation information, and the imaged positional deviation corresponding to the moving direction position of the table at the time of imaging the work reference mark obtained from the imaged positional deviation information.

A first work position information obtaining apparatus is an apparatus including:

a table on which a work is placed;

an imaging means for imaging over the surface of the table;

a moving means for moving the table relative to the imaging means;

a moving direction position information obtaining means for obtaining moving direction position information representing a moving direction position of the table with respect to the imaging means; and

a work position information obtaining means for obtaining work position information representing a position of the work with respect to the table based on imaged table information and imaged work information obtained by imaging a table reference mark provided on the table being relatively moved and a work reference mark provided on the work placed on the table, and the moving direction position information of the table at the time of imaging the table reference mark and at the time of imaging the work reference mark obtained by the moving direction position information obtaining means, wherein the apparatus further includes:

a work position obtaining storage means for storing imaged positional deviation information, obtained in advance, representing a positional deviation, which indicates displacement of the table that occurs when the table is moved relative to the imaging means, in association with each of the moving direction positions of the table; and

a work position obtaining arithmetic means for performing an arithmetic operation for eliminating an error included in the work position information arising from the difference between each imaged positional deviation using the imaged positional deviation corresponding to the moving direction position of the table at the time of imaging the table reference mark obtained from the imaged positional deviation information, and the imaged positional deviation corresponding to the moving direction position of the table at the time of imaging the work reference mark obtained from the imaged positional deviation information.

The work position obtaining arithmetic means may be a means for performing the arithmetic operation for calculating the error using the imaged information at the time of imaging the table reference mark and the imaged information at the time of imaging the work reference mark.

The imaged positional deviation information may be information representing an imaged positional deviation in the moving direction, an imaged positional deviation in an orthogonal moving direction which is orthogonal to the moving direction and parallel to a moving plane, and an imaged positional deviation in a rotational direction around an orthogonal moving plane direction which is orthogonal to the moving plane.

The first work position information obtaining apparatus may include an imaged positional deviation measuring means for measuring the imaged positional deviation, and the work position obtaining arithmetic means may be a means for performing the arithmetic operation for eliminating the error using the imaged positional deviation measured by the imaged positional deviation measuring means at a time in one or more previous reciprocal movement of the table while the table is reciprocally moved repeatedly by the moving means.

A second work position information obtaining method is a method including the steps of:

moving a table with a work placed thereon relative to an imaging means for imaging over the surface of the table;

obtaining imaged table information and imaged work information by imaging a table reference mark provided on the table being moved and a work reference mark provided on the work placed on the table, and obtaining moving direction position information representing moving direction positions of the table when the table reference mark and work reference mark are imaged; and

obtaining work position information representing a position of the work with respect to the table based on the imaged table information, imaged work information, and moving direction position information, wherein:

imaged positional deviation information representing an imaged positional deviation, which indicates displacement of the table that occurs when the table is moved relative to the imaging means, in association with each of the moving direction positions of the table is obtained in advance; and

the work position information is made free of an error arising from the displacement of the table by relatively moving the table and imaging means such that the imaged positional deviation corresponding to the moving direction position of the table at the time of imaging the table reference mark obtained from the imaged positional deviation information is cancelled when imaging the table reference mark, and relatively moving the table and imaging means such that the imaged positional deviation corresponding to the moving direction position of the table at the time of imaging the work reference mark obtained from the imaged positional deviation information is cancelled when imaging the work reference mark.

A second work position information obtaining apparatus is an apparatus including:

a table on which a work is placed;

an imaging means for imaging over the surface of the table;

a moving means for moving the table relative to the imaging means;

a moving direction position information obtaining means for obtaining moving direction position information representing a moving direction position of the table with respect to the imaging means; and

a work position information obtaining means for obtaining work position information representing a position of the work with respect to the table based on imaged table information and imaged work information obtained by imaging a table reference mark provided on the table being relatively moved and a work reference mark provided on the work placed on the table, and the moving direction position information of the table at the time of imaging the table reference mark and at the time of imaging the work reference mark obtained by the moving direction position information obtaining means, wherein:

the apparatus further includes:
a work position obtaining storage means for storing imaged positional deviation information, obtained in advance, representing a positional deviation, which indicates displacement of the table that occurs when the table is moved relative to the imaging means, in association with each of the moving direction positions of the table;
a work position obtaining moving means for relatively moving the table and imaging means; and
a work position obtaining control means for controlling the work position obtaining moving means to cause the table and imaging means to be relatively moved such that the imaged positional deviation corresponding to the moving direction position of the table at the time of imaging the table reference mark obtained from the imaged positional deviation information is cancelled when imaging the table reference mark, and to cause the table and imaging means to be relatively moved such that the imaged positional deviation corresponding to the moving direction position of the table at the time of imaging the work reference mark obtained from the imaged positional deviation information is cancelled when imaging the work reference mark, and

the work position information obtained by the work position information obtaining means is made free of an error arising from the displacement of the table.

The work position obtaining control means may be a means for causing only the imaging means to be moved.

The work position obtaining control means may be a means for causing only the table to be moved.

The imaged positional deviation information may be information representing an imaged positional deviation in the moving direction, an imaged positional deviation in an orthogonal moving direction which is orthogonal to the moving direction and parallel to a moving plane, and an imaged positional deviation in a rotational direction around an orthogonal moving plane direction which is orthogonal to the moving plane.

The second work position information obtaining means may include an imaged positional deviation measuring means for measuring the imaged positional deviation, and the work position obtaining control means may be a means for controlling the work position obtaining moving means using the imaged positional deviation measured by the imaged positional deviation measuring means at a time in one or more previous reciprocal movement of the table while the table is reciprocally moved repeatedly by the moving means.

The work position obtaining storage means may be a means that allows the imaged positional deviation information stored therein to be updated every time the table is reciprocally moved by the moving means.

The first work position information obtaining means may include an imaged positional deviation measuring means for measuring the imaged positional deviation, and an imaged positional deviation may be measured by the imaged positional deviation measuring means in an outward movement of the table driven by the moving means, and table reference mark and work reference mark may be imaged by the imaging means in a homeward movement of the table driven by the moving means.

The second work position information obtaining means may include an imaged positional deviation measuring means for measuring the imaged positional deviation, and an imaged positional deviation may be measured by the imaged positional deviation measuring means in an outward movement of the table driven by the moving means, and table reference mark and work reference mark may be imaged by the imaging means in a homeward movement of the table driven by the moving means.

The imaging means may be a means for obtaining the imaged table information and imaged work information by imaging the table reference mark provided on the table being moved and work reference mark provided on the work placed on the table at different timings with each other.

The inventors of the present invention found that displacement of a table being moved arising from, for example, changes in the environmental temperature is an error factor in obtaining the position of a work with respect to the table, which has led to the present invention.

That is, the position of the work with respect to the table is obtained, in the past, on the assumption that the displacement of the table does not occur during the movement of the table from the imaging of a table reference mark provided on the table to the imaging of a work reference mark provided on the work. The inventors of the present invention found that the displacement of the table that occurs during the movement of the table from the imaging of the table reference mark to the imaging of the work reference mark is an error factor in obtaining the position of the work with respect to the table.

According to the first work position information obtaining method and apparatus of the present invention, an error included in the work position information arising from the difference between each positional deviation is eliminated using the imaged positional deviation corresponding to the moving direction position of the table at the time of imaging the table reference mark obtained from the work position obtaining positional deviation information representing an imaged positional deviation, which indicates displacement of the table that occurs when the table is moved relative to the imaging means, in association with the moving direction position, and the imaged positional deviation corresponding to the moving direction position of the table at the time of imaging the work reference mark obtained from the work position obtaining positional deviation information, so that the position of the work with respect to the table may be obtained with high accuracy.

If the work position obtaining arithmetic means is a means for performing an arithmetic operation for obtaining an error included in the work position information using the imaged information at the time of imaging the table reference mark and work reference mark, the position of the work with respect to the table may be obtained with high accuracy.

According to the second work position information obtaining method and apparatus of the present invention, the work position obtaining positional deviation information representing an imaged positional deviation, which indicates displacement of the table that occurs when the table is moved relative to the imaging means, in association with the moving direction position is obtained in advance, and the work position information is made free of an error arising from the displacement of the table by relatively moving the table and imaging means such that the imaged positional deviation corresponding to the moving direction position of the table at the time of imaging the table reference mark obtained from the imaged positional deviation information is cancelled when imaging the table reference mark, and relatively moving the table and imaging means such that the imaged positional deviation corresponding to the moving direction position of the table at the time of imaging the work reference mark obtained from the imaged positional deviation information is cancelled when imaging the work reference mark, so that the position of the work with respect to the table may be obtained with high accuracy.

If the work position obtaining control means is a means for moving either one of the imaging means and table, the structure of the work position obtaining control means may be simplified, the position of the work with respect to the table may be obtained easily.

If the work position obtaining positional deviation information is information representing an imaged positional deviation in the moving direction, an imaged positional deviation in an orthogonal moving direction which is orthogonal to the moving direction and parallel to a moving plane, and an imaged positional deviation in a rotational direction around an orthogonal moving plane direction which is orthogonal to the moving plane, the position of the work with respect to the table may be obtained with certainty.

### BRIEF DESCRIPTION OF THE DRAWINGS

FIG. 1 illustrates a schematic configuration of the work position information obtaining apparatus of the present invention.

FIG. 2A1 indicates a position of a non-displaced table when the reading of the moving direction position thereof is p1.

FIG. 2A2 indicates the position of the non-displaced table when the reading of the moving direction position thereof is p2.

FIG. 2A3 indicates the position of the non-displaced table when the reading of the moving direction position thereof is p3.

FIG. 2A4 indicates the position of the non-displaced table when the reading of the moving direction position thereof is p4.

FIG. 2A5 indicates the position of the non-displaced table when the reading of the moving direction position thereof is pe.

FIG. 2B1 illustrates the field of imaging section when the reading of the moving direction position is p1 under no table displacement is observed.

FIG. 2B2 illustrates the field of imaging section when the reading of the moving direction position is p2 under no table displacement is observed.

FIG. 2B3 illustrates the field of imaging section when the reading of the moving direction position is p3 under no table displacement is observed.

FIG. 2B4 illustrates the field of imaging section when the reading of the moving direction position is p4 under no table displacement is observed.

FIG. 2B5 illustrates the field of imaging section when the reading of the moving direction position is pe under no table displacement is observed.

FIG. 3A1 indicates the position of a displaced table when the reading of the moving direction position thereof is p1.

FIG. 3A2 indicates the position of the displaced table when the reading of the moving direction position thereof is p2.

FIG. 3A3 indicates the position of the displaced table when the reading of the moving direction position thereof is p3.

FIG. 3A4 indicates the position of the displaced table when the reading of the moving direction position thereof is p4.

FIG. 3A5 indicates the position of the displaced table when the reading of the moving direction position thereof is pe.

FIG. 3B1 illustrates the field of imaging section when the reading of the moving direction position is p1 under table displacement is observed.

FIG. 3B2 illustrates the field of imaging section when the reading of the moving direction position is p2 under table displacement is observed.

FIG. 3B3 illustrates the field of imaging section when the reading of the moving direction position is p3 under table displacement is observed.

FIG. 3B4 illustrates the field of imaging section when the reading of the moving direction position is p4 under table displacement is observed.

FIG. 3B5 illustrates the field of imaging section when the reading of the moving direction position is pe under table displacement is observed.

FIG. 4A illustrates changes in imaged positional deviation δx with respect to moving direction positions p of the table.

FIG. 4B illustrates changes in imaged positional deviation δy with respect to moving direction positions p of the table.

FIG. 4C illustrates changes in imaged positional deviation δθ with respect to moving direction positions p of the table.

FIG. 5 illustrates a method for correcting displacement of the table in the rotational direction.

FIG. 6 illustrates the state in which each partial image pattern is correctly plotted on the table.

FIG. 7A illustrates changes in imaged positional deviation δx with respect to moving direction positions q of the table.

FIG. 7B illustrates changes in imaged positional deviation δy with respect to moving direction positions q of the table.

FIG. 7C illustrates changes in imaged positional deviation δθ with respect to moving direction positions q of the table.

FIG. 8 illustrates the state in which each partial image pattern is plotted without correcting displacement.

FIG. 9A illustrates the state in which a glass plate of a second image plotting correction moving section becomes horizontal.

FIG. 9B illustrates the state in which the glass plate of the second image plotting correction moving section is inclined.

FIG. 10 illustrates the state in which each partial image pattern is plotted on a correct position of a work which is displaced from a predetermined position of the table.

FIG. 11 illustrates the state in which image plotting is performed on a work using a plurality of image plotting heads.

FIG. 12 illustrates the structure of the image plotting head.

FIG. 13 illustrates a process of generating a DMD reset signal.

### BEST MODE FOR CARRYING OUT THE INVENTION

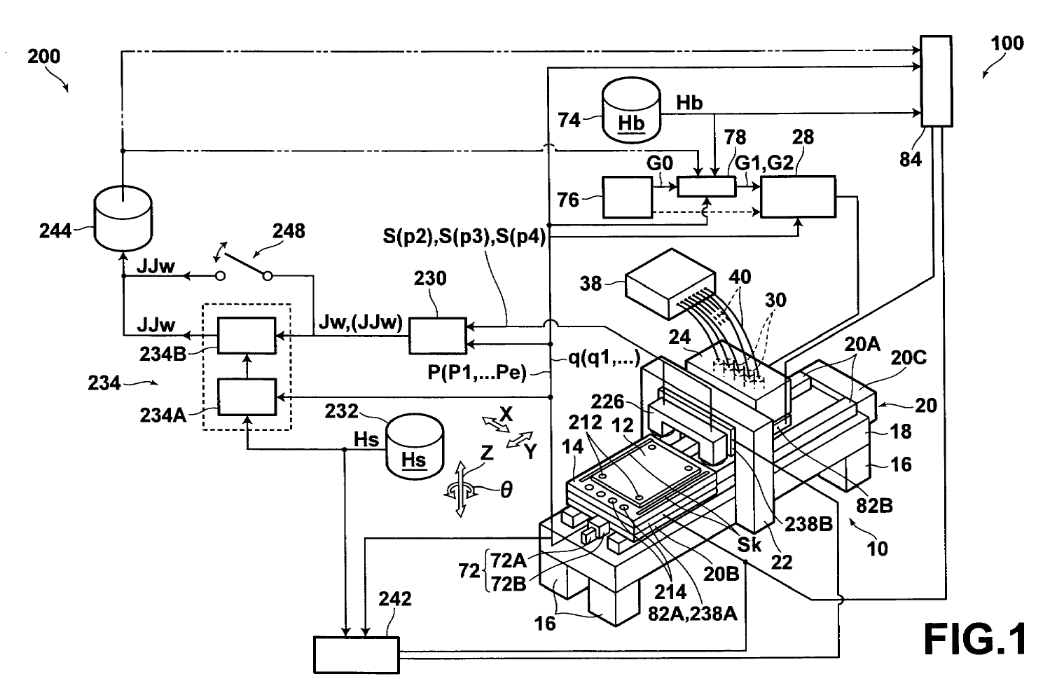

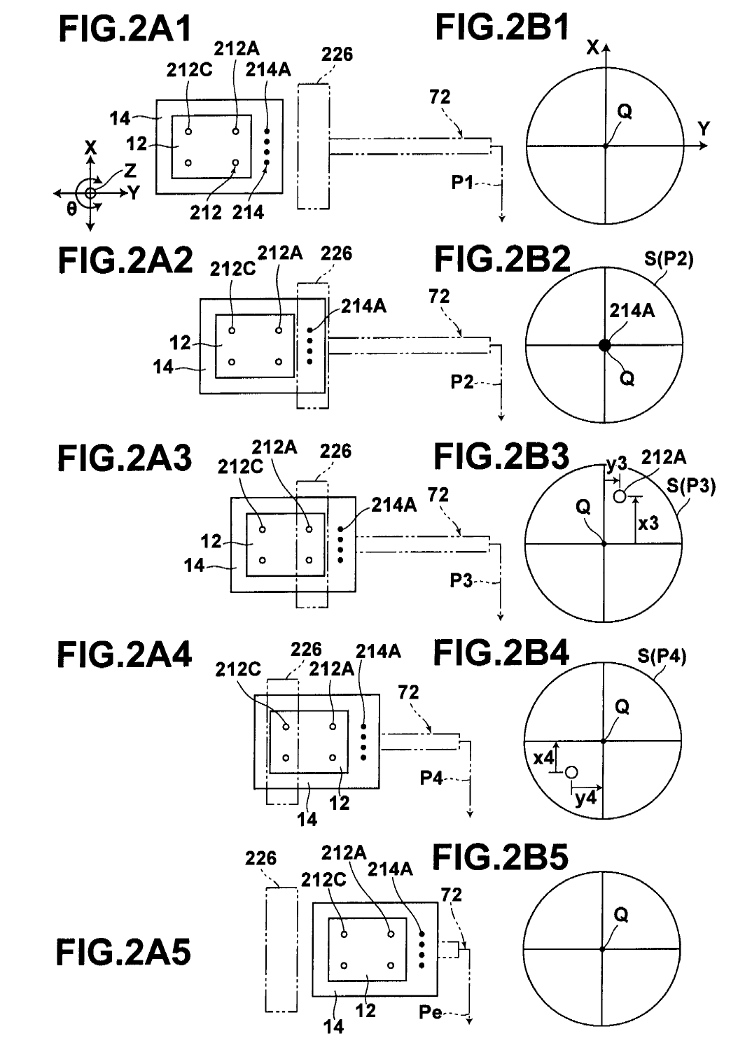

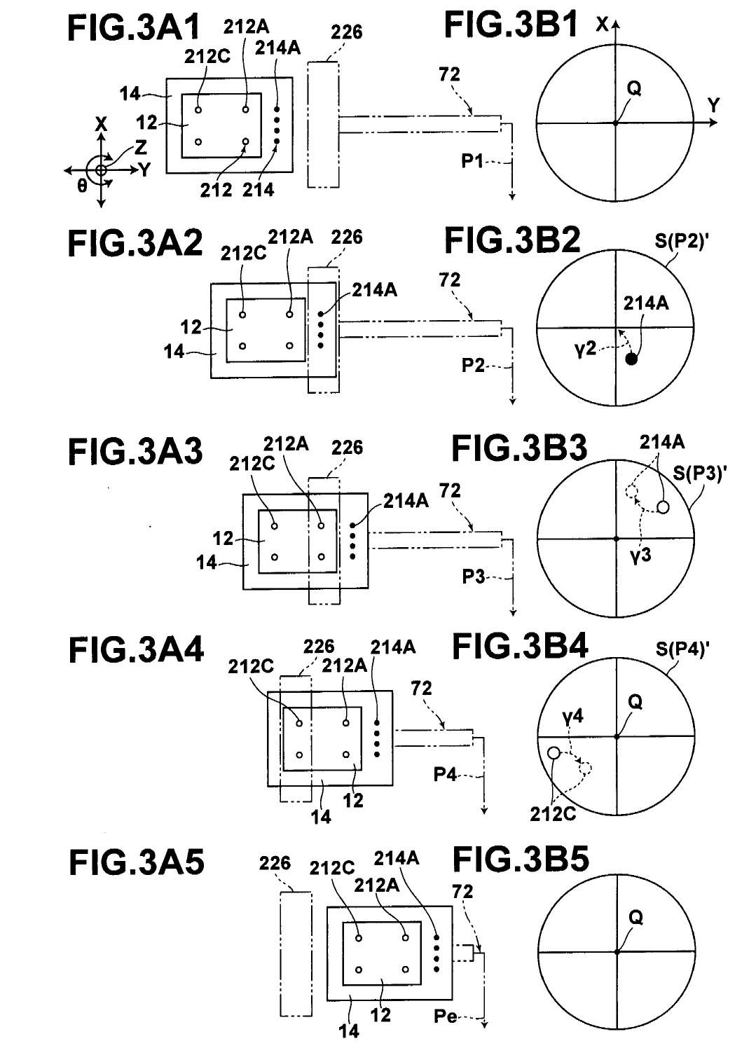

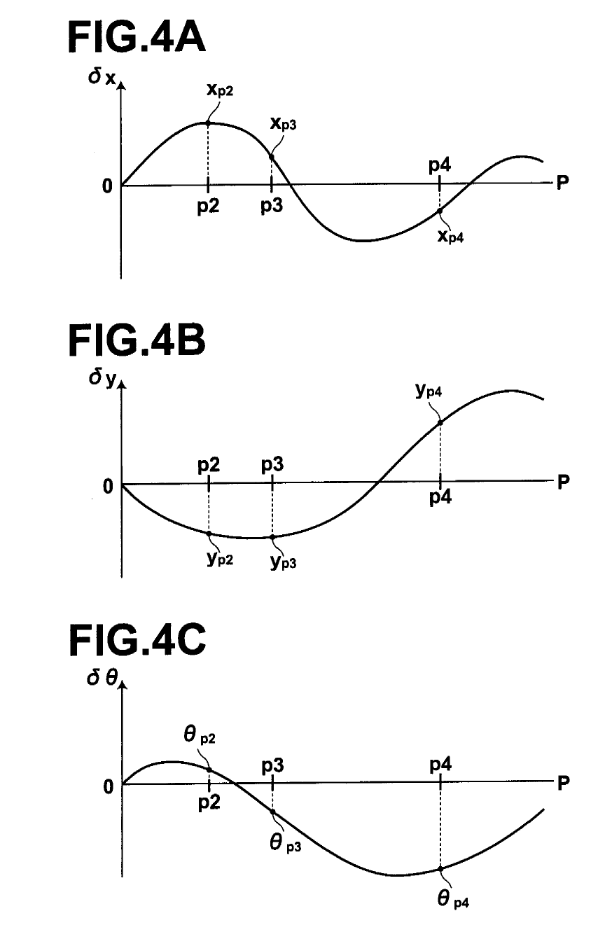

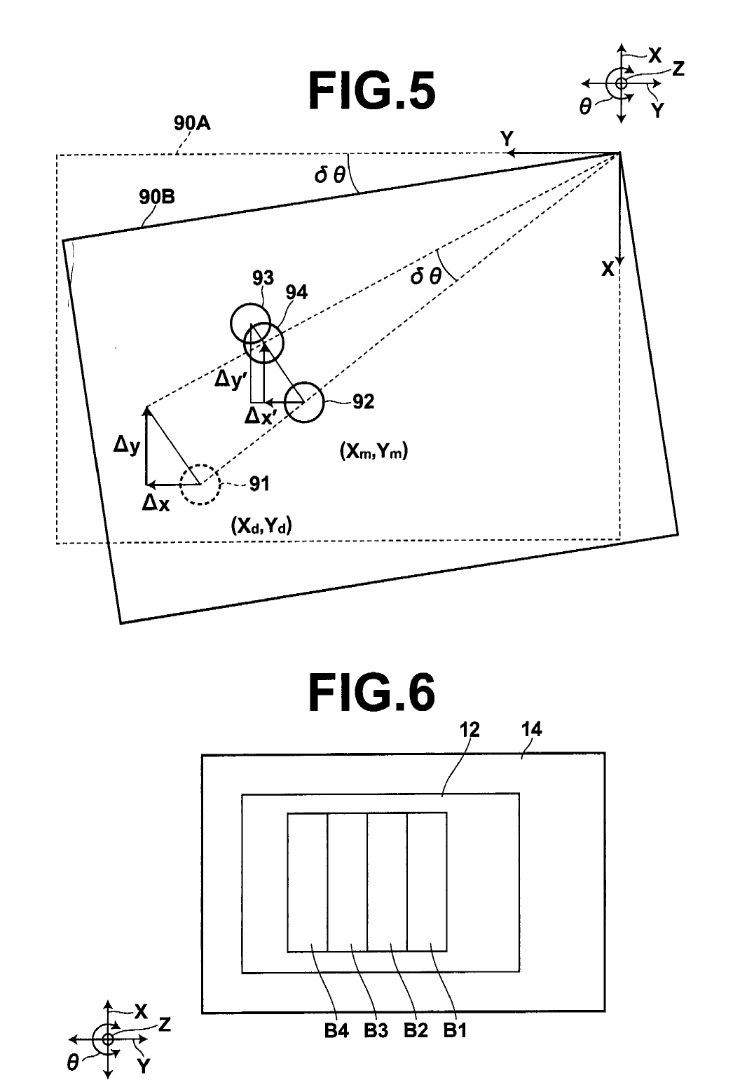

Hereinafter, an embodiment of a work position information obtaining apparatus that performs the work position information obtaining method of the present invention will be described. FIG. 1 is a schematic configuration diagram of an image plotting apparatus incorporating the work position information obtaining apparatus according to an embodiment of the present invention. FIG. 2 illustrates imaging of reference marks by the work position information obtaining apparatus under no displacement. FIG. 3 illustrates imaging of reference marks by the work position information obtaining apparatus under displacement. FIG. 4 illustrates positional deviations of the table associated with table moving direction positions. FIG. 5 illustrates a method for correcting displacement in the rotational direction.

The work position information obtaining apparatus 200 according to the present embodiment differs from the image plotting apparatus 100, and the system shown is constructed by using a portion of each of them.

### [Schematic Structure of Image Plotting Apparatus 100]

Hereinafter, the schematic configuration of the image plotting apparatus 100 will be described.

The image plotting apparatus 100 includes: a table 14 on which a work 12 is placed; an image plotting means 30 for performing image plotting on the work 12 place on the table 14; a moving section 20 for relatively moving the table 14 with respect to the image plotting means 30; a linear encoder 72, which is a moving direction position information obtaining section for obtaining moving direction position information representing a moving direction position (a position in the Y direction in the plotting) of the table 14 with respect to the image plotting means 30; an image plotting control section 28 for performing control such that, while the table 14 is being moved with respect to the image plotting means 30 by the moving section 20, the image plotting means sequentially performs image plotting of partial image patterns, each corresponding to each moving direction position obtained by the linear encoder, on the work 12 placed on the table 14, thereby a predetermined pattern is plotted on the work 12; and an image data memory 76 having therein original image data Go used for plotting an image pattern under control of the image plotting control section 28.

As for the work 12, a printed circuit board, a display glass substrate, or a substrate coated with a photosensitive material for making a color filter glass substrate may be used.

The linear encoder 72 includes a linear scale 72A disposed on a mounting platform 18, and a reading section 73B disposed on a support platform 20B of a moving section 20 to be described later, and outputs a position signal (designated by a reference symbol p or q) representing a moving direction position of the table 14.

The moving section 20 includes guides 20A for guiding the table 14, the support platform 20B for supporting the table 14, and a drive section 20C for driving the support platform 20B. When the table 14 is moved by the moving section 20, displacement of the table 14 occurs, but the displacement is reproducible.

It is noted that the structure of the drive mechanism is omitted, but any known drive mechanism may be used. For example, as for the slide mechanism, a ball rail system in which a moving platform is moved on rails, an air slide system, or the like may be used. As for the drive power transfer system, a cam mechanism, link mechanism, rack-and-pinion mechanism, ball screw ball push mechanism, air slide mechanism, piston-cylinder mechanism, or the like may be used. As for the drive source, a motor, hydraulic actuator, air actuator, or the like may be used.

The structure of the image plotting means 30 will be described in detail later.

The image plotting apparatus 100 further includes: an image plotting position deviation storage section 74 for storing image plotting position deviation information Hb, obtained in advance, representing an image plotting position deviation, which indicates displacement of the table 14 relative to the image plotting means 30 that occurs when the table 14 is moved by the moving section 20, in association with each of the moving direction positions (p) of the table 14; and an image data correction section 78 for correcting the original image data Go stored in the image data memory 76 such that the image plotting position deviation, corresponding to the moving direction position (p) indicated by the position signal, obtained from the image plotting position deviation information Hb stored in the image plotting position deviation storage section 74 is cancelled. The image plotting means 30 plots partial image patterns using the corrected image data G1 obtained by correcting the original image data Go in the image data correction section 78.

The image plotting apparatus still further includes: a first image plotting correction moving section 82A for relatively moving the table 14 and image plotting means 30; a second image plotting correction moving section 82B for relatively moving the table 14 and an image plotting beam outputted from the image plotting means 30; and an image plotting correction control section 84 for controlling the first and second image plotting correction moving sections 82A, 82B to cause a relative movement between the table 14 and image plotting means 30 when partial image patterns are plotted by the image plotting means 30 such that the image plotting position deviations, corresponding to the moving direction position (p) when the partial image patterns are plotted, obtained from the image plotting position deviation information Hb stored in the image plotting position deviation storage section 74 is cancelled. This allows the partial image patterns to be plotted by the image plotting means 30 while the table 14 and image plotting means 30 are being moved relatively such that the image plotting position deviations are cancelled.

The moving direction position (p) used by the image plotting correction control section 84 may be obtained from the linear encoder 72.

The first image plotting correction moving section 82A is disposed on the support platform 20B of the moving section 30 to support the table 14, thereby the relative position of the moving section 20 and support platform 20B is moved. The second image plotting correction moving section 82B moves the position of an image plotting beam outputted from an image plotting head, which is the image plotting means 30. The referent of “image plotting means” may means only an image plotting beam outputted from an image plotting head, or both an image plotting head and an image plotting beam outputted therefrom. The second image plotting correction moving section 82B will be described in detail later.

[Directions in which Image Plotting Position Deviations are Cancelled]

The image plotting position deviation representing displacement of the table 14 relative to the image plotting means 30 may include an image plotting position deviation δy in the moving direction (Y direction in the drawings), an image plotting position deviation δx in an orthogonal moving direction (arrow X direction in the drawing) which is orthogonal to the moving direction and parallel to a moving plane (X-Y plane in the drawing), an image plotting position deviation δθ in a rotational direction (indicated by the arrow θ in the drawing) around an orthogonal moving plane direction (arrow Z direction in the drawing) which is orthogonal to the moving plane, as well as rolling, pitching, and an image plotting position deviation in an orthogonal moving plane direction (allow Z direction in the drawing), and the like.

For the types of image plotting position deviations to be stored in the image plotting position deviation storage section 74 as the image plotting position deviation information Hb, types of image plotting position deviations to be cancelled by the image data correction section 78, or types of image plotting position deviations to be cancelled by the first and second image plotting correction moving sections 82A, 82B through control of the image plotting correction control section 84, all of the varieties of the image plotting position deviations described above or some of them may be used.

It is noted that the image plotting position deviation δθ may be a rotation angle around the orthogonal moving plane direction (arrow Z direction in the drawings) axis passing through the center position of the table plane.

Displacement in the moving direction (Y direction in the drawings) may occur due to, for example, a deviation from a true value in the position signal outputted from the linear encoder 72 caused a distortion or the like of the scale 72 of the linear encoder 72 arising from a change in temperature or a change with time thereof. In such a case, even if the table 14 is tried to be controlled so as to be moved by the same distance per unit time, if the table 14 is moved based on the scale 72 without correction, the table 14 is not moved correctly by the same distance per unit time.

The image plotting position deviation δθ in the rotational direction around the orthogonal moving plane direction axis may be allocated to a component of image plotting position deviation δy in the moving direction, and a component of image plotting position deviation δx in the orthogonal moving direction. Thus, canceling effects identical to those obtainable by the cancellation of three types of image plotting position deviations, δx, δy, and δθ may be obtained using two types of image plotting position deviations δx and δy divided from an image plotting position deviation δθ.

When canceling the image plotting position deviations δx, δy, and δθ, an alignment stage (Model CMX, produced by THK) capable of performing alignment in the x, y, and θ directions, or the like may be used as the first image plotting correction moving section 82A. Where more types of image plotting position deviations are cancelled, the first image plotting correction moving section 82A may be constructed by combining a plurality of the alignment stages described above, or moving means including well-known piezo devices. The second image plotting correction moving section 82B may also be constructed using identical components described above.

### [Structure of Work Position Information Obtaining Apparatus 200]

Hereinafter, the structure of the work position information obtaining apparatus 200 will be described. The constituent elements of the image plotting apparatus 100 described above are given the same reference numerals.

The work position information obtaining apparatus 200 includes: the table 14 on which a work 12 is placed; an imaging section 226 for imaging over the surface of the table 14; the moving section 20 for moving the table 14 relative to the imaging means 226; the linear encoder 72 which is a moving direction position information obtaining section for obtaining moving direction position information representing a moving direction position (p) of the table 14 with respect to the imaging means 226; and a work position information obtaining section 230 for obtaining work position information Jw representing a position of the work 12 with respect to the table 14 based on imaged table information and imaged work information obtained by imaging a table reference mark 214 provided on the table 14, which is moved relative to the imaging section 226, and a work reference mark 212 provided on a work placed on the table 14 with the imaging section 226 at different timings.

The work position information obtaining apparatus 200 further includes: a work position obtaining storage section 232 for storing imaged positional deviation information Hs, obtained in advance, representing an imaged positional deviation δ, which indicate displacement of the table 14 that occurs when the table 14 is moved relative to the imaging section 226, associated with the moving direction position (p) of the table 14; and a work position obtaining arithmetic section 234 for performing an arithmetic operation for canceling an error included in the work position information arising from the difference between each imaged positional deviation using an imaged positional deviation δ, which corresponds to a moving direction position (p) of the table 14 obtained from the linear encoder 72 at the time of imaging the table reference mark, obtained from the imaged positional deviation information Hs, and an imaged positional deviation δ, which corresponds to a moving direction position (p) of the table 14 obtained from the linear encoder 72 at the time of imaging the work reference mark, obtained from the imaged positional deviation information Hs. This allows corrected work position information JJw to be obtained, in which an error arising from displacement of the table 14 included in the work position information Jw obtained by the work position information obtaining section 230 is eliminated.

The work position obtaining arithmetic section 234 includes: an imaged positional deviation information obtaining section 234A for obtaining the imaged positional deviation δ corresponding to the moving direction position (p) of the table 14 obtained from the linear encoder 72 at the time of imaging the table reference mark, and the imaged positional deviation δ corresponding to the moving direction position (p) of the table 14 obtained from the linear encoder 72 at the time of imaging the work reference mark from the imaged positional deviation information Hs; and an error canceling arithmetic section 234B for performing an arithmetic operation for canceling the error arising from the difference between each imaged positional deviation included in the work position information.

The work position information obtaining apparatus 200 still further includes: a first work position obtaining moving section 238A, which is a work position obtaining moving means for relatively moving the table and imaging section; a second work position obtaining moving section 238B; and a work position obtaining control section 242 for controlling the first and second work position obtaining moving sections 238A, 238B to cause the table 14 and imaging section 226 to be relatively moved such that the imaged positional deviation corresponding to the moving direction position (p) of the table at the time of imaging the table reference marks obtained from the imaged positional deviation information Hs when imaging the table reference mark, and to cause the table 14 and imaging section 226 to be relatively moved such that the imaged positional deviation corresponding to the moving direction position (p) of the table at the time of imaging the table reference mark obtained from the imaged positional deviation information Hs when imaging the work reference mark. This allows the work position information Jw, to be obtained by the work position information obtaining section 230, to be information that does not include an error arising from displacement of the table 14. That is, corrected work position information JJw may be obtained and outputted from the work position information obtaining section 230.

The corrected work position information JJw is sent to a corrected work position information storage section 244 and stored therein.

[Directions in which Imaged Positional Deviation are Cancelled]

As in the image plotting apparatus 100 describe above, positional deviations in various directions may be pointed out as imaged positional deviations that indicate displacement of the table 14 relative to the imaging section 226.

For the types of imaged positional deviations to be stored in the work position obtaining storage section 232 as the imaged positional deviation information, types of imaged positional deviations to be eliminated by the work position obtaining arithmetic section 234, or types of imaged positional deviations to be cancelled by the first and second work position obtaining moving sections 238A, 238B through control of the work position obtaining control section 242, all of the varieties of the positional deviations already explained as the image plotting position deviations or some of them may be used.

It is noted that the image plotting position deviation δθ may be a rotation angle around the orthogonal moving plane direction (arrow Z direction in the drawings) axis passing through the center position of the table plane.

The imaged positional deviation δθ in the rotational direction around the orthogonal moving plane direction axis may be allocated to a component of imaged positional deviation δy in the moving direction, and a component of imaged positional deviation δx in the orthogonal moving direction. Thus, displacement canceling effects identical to those obtainable by the use of three types of imaged positional deviations, δx, δy, and δθ may be obtained using two types of imaged positional deviations δx and δy divided from an imaged positional deviation δθ.

When canceling the imaged positional deviations δx, δy, and δθ, the alignment stage (Model CMX, produced by THK) capable of performing alignment in the x, y, and θ directions described above, or the like may be used as the first work position obtaining moving section 238A. Where more types of imaged positional deviations are cancelled, the first work position obtaining moving section 238A may be constructed by combining a plurality of the alignment stages described above, or moving means including well-known piezo devices or air cylinders. The second image plotting correction moving section 82B may also include the identical components described above. The second work position obtaining moving section 238B may also be constructed using identical components described above.

It is noted that the first work position obtaining moving section 238A may be a section common to the first image plotting correction moving section 82A.

### [Operation of Work Position Information Obtaining Apparatus 200]

Next, an operation of the work position information obtaining apparatus 200 will be described. FIGS. 2A1 to 2A5 illustrate the state in which the table is moved without displacement and each reference mark is imaged. FIGS. 2B1 to 2B5 illustrate the field of the imaging section in that state. FIGS. 3A1 to 3A5 illustrate the state in which the table is moved with displacement and each reference mark is imaged without correcting the displacement. FIGS. 3B1 to 3B5 illustrate the field of the imaging section in that state. Hereinafter, the imaged table information and imaged work information are also simply referred to as imaged information.

First, an operation for obtaining the position of the work 12 with respect to the table 14 when the table 14 is moved by the moving section 20 without displacement will be described. The displacement of the table includes a reading error of the linear encoder 72 for the moving direction position (p).

As illustrated in FIG. 2A1, the moving direction position read by the linear encoder 72 when the table 14 is located in the initial position is p1. As illustrated in FIG. 2B1, nothing appears in the field of the imaging section 226 when the table 14 is located in the initial position.

As illustrated in FIG. 2A2, when the table 14 is moved by the moving section 20 and the moving direction position read by the linear encoder 72 is p2, a table reference mark 214A, which is one of several table reference marks 214, is imaged by the imaging section 226 to obtain imaged information S(p2) illustrated in FIG. 2B2.

Then, as illustrated in FIG. 2A3, when the table 14 is further moved by the moving section 20 and the moving direction position read by the linear encoder 72 is p3, a work reference mark 212A, which is one of several work reference marks 212, is imaged by the imaging section 226 to obtain imaged information S(p3) illustrated in FIG. 2B3.

Thereafter, as illustrated in FIG. 2A4, when the table 14 is further moved by the moving section 20 and the moving direction position read by the linear encoder 72 is p4, a work reference mark 212C, which is one of several work reference marks 212, is imaged by the imaging section 226 to obtain imaged information S(p3) illustrated in FIG. 2B4.

Finally, as illustrated in FIG. 2A5, when the table 14 is moved to the terminal end of the moving section 20, the moving direction position read by the linear encoder 72 is pe. As illustrated in FIG. 2B5, nothing appears in the field of the imaging section 226 when the table is located in the terminal end.

According to the imaged information S(p2) obtained when the moving direction position read by the linear encoder 72 is p2, the table reference mark 214A is located in a reference position Q which is the center of the field of the imaging section 226.

According to the imaged information S(p3) obtained when the moving direction position read by the linear encoder 72 is p3, the work reference mark 212A is deviated from the reference position Q by x3 in the X direction and y3 in the Y direction.

According to the imaged information S(p4) obtained when the moving direction position read by the linear encoder 72 is p4, the work reference mark 212C is deviated from the reference position Q by x4 in the X direction and y4 in the Y direction.

Accordingly, the distance LY3 in theY direction from the table reference mark 214A to the work reference mark 212A may be obtained by the formula, LY3=(p−p2)−y3. Further, the distance LX3 in the X direction from the table reference mark 214A to the work reference mark 212A may be obtained by the formula, LX3=x3.

The distance LY4 in the Y direction from the table reference mark 214A to the work reference mark 212C may be obtained by the formula, LY4=(p4−p3)−y4. Further, the distance LX4 in the X direction from the table reference mark 214A to the work reference mark 212C may be obtained by the formula, LX4=x4.

If no table displacement occurs when the table 14 is moved by the moving section 20, the position of the work 12 with respect to the table 14 may be obtained in the manner as described above.

Here, if table displacement occurs when the table 14 is moved by the moving section 20, for example, the following imaged information including an error of displacement is obtained through an identical operation to that described above. That is, in the imaged information S(p2)′ obtained when the moving direction position read by the linear encoder 72 is p2, the table reference mark 214A is deviated by γ2 from the reference position Q which is the center of the field of the imaging section 226.

In the imaged information S(p3)′ obtained when the moving direction position read by the linear encoder 72 is p3, the work reference mark 212A deviated from the reference position Q by x3 in the X direction and y3 in the Y direction is further deviated by γ3.

In the imaged information S(p4)′ obtained when the moving direction position read by the linear encoder 72 is p4, the work reference mark 212C deviated from the reference position Q of the imaging section 226 by x4 in the X direction and y4 in the Y direction is further deviated by γ4.

The deviations γ2, γ3, and γ4 occur due to difference in positional deviations of the table 14 at the respective times of imaging when the moving direction positions are p2, p3, and p4 respectively.

In the mean time, the imaged positional deviation information obtained in advance by measurement and stored in the work position obtaining storage section 232 is information representing positional deviations of the table 14 in the X, Y, and θ directions associated with the moving direction positions (p) of the table 14 obtained by the linear encoder 72.

### [Measurement of Positional Deviations]

Imaged positional deviations to be stored in the work position obtaining storage section 232, and image plotting position deviations to be stored in the image plotting position deviation storage section 74 may be measured in the following manner by an imaged positional deviation measuring means, and an image plotting position deviation measuring means respectively.

That is, the positional deviations of the table 14 in the X, Y, and θ directions associated with the moving direction positions (p) of the table 14 may be obtained based on the data obtained by disposing a reference scale Sk extending in the moving direction (Y direction) on the table 14 at each end in the X direction, and associating the readings of the two reference scales read by the imaging section 226 while moving the table 14 by the moving section 20 with the moving direction positions (p) obtained by the linear encoder 72.

The measurement of the positional deviations may be performed by a method employing a laser end measuring machine. That is, disposing a corner cube on the table 14 at each end in the X direction, associating the values, obtained by the measurement with one of the corner cubes being set as the target of the laser end measuring machine while moving the table 14 by the moving section 20, with the moving direction positions (p) obtained by the linear encoder 72, and associating the values, obtained by the measurement with the other corner cube being set as the target of the laser end measuring machine while moving the table 14 by the moving section 20, with the moving direction positions (p) obtained by the linear encoder 72, thereby the positional deviations of the table 14 in the X, Y, and θ directions associated with the moving direction positions (p) of the table 14 may be obtained based on these two types of position information.

The measuring method of the positional deviations described above may be used for measuring image plotting position deviations in the image plotting apparatus and imaged positional deviations in the work position information obtaining apparatus.

In the measuring method for measuring positional deviations in the image plotting apparatus, the table on which a work is placed is moved relative to the image plotting means 30, and a plurality of test pattern images are plotted on the work by the image plotting means 30 with the moving direction positions (p) obtained by the linear encoder 72 being associated therewith. Then, positional deviations are obtained in association with the moving direction positions (p) based on the plotted state of the plurality of test pattern images. In this way, the positional deviations in the X, Y, and θ directions may be obtained.

The imaged positional deviation δ represented by the imaged positional deviation information obtained in the manner as described above indicates an imaged positional deviation δx in the X direction, an imaged positional deviation δy in the Y direction, and an imaged positional deviation δθ, which are associated with each of the moving direction positions, as illustrated in FIGS. 4A to 4C. Here, it is understood that the deviation γ2 is displaced by a positional deviation of xp2 in the X direction, by a positional deviation of yp2 in the Y direction, and by a positional deviation of θp2 at the moving direction position p2. This relationship may be expressed by a function, γ2=Fp2 (xp2, yp2, θp2). Likewise, γ3 and γ4 may be expressed as γ3=Fp3 (xp3, yp3, θp3), and γ4=Fp4 (xp4, yp4, θp4).

It is noted that the θ component may be allocated to X and Y components and expressed, for example, by a function of two directions X and Y, as γ2=Fp2 (xp2′, yp2′) for use with cancellation of an error. When obtaining the position of a work with respect to the table 14, the imaged information S(p2)′, imaged information S(p3)′, and imaged information S(p4)′ which include displacement of the table 14 arising from the movement thereof by the moving section 20 illustrated in FIG. 4 are changed to the state where the displacement is not included, i.e., the state of imaged information S(p2), imaged information S(p3), and imaged information S(p4) prior to the occurrence of the deviations γ2, γ3, and γ4 illustrated in FIG. 3. Then, the position of the work with respect to the table 14 is obtained by the method described above.

In order to obtain a correct position of the work 12 with respect to the table 14 by correcting the positional deviations described above, the work position information obtaining apparatus 200 includes two different correction methods: data correction and mechanical correction.

### [Data Correction Method]

The data correction method will be described first.

The imaged positional deviation information obtaining section 234A obtains an imaged positional deviation δ2=xp2, yp2, and θp2 associated with the moving direction position p2 read by the linear encoder 72 at the time of imaging the table reference marks from imaged positional deviation information Hs (FIG. 4) stored in the work position obtaining storage section 232 in advance. Further, the imaged positional deviation information obtaining section 234A obtains an imaged positional deviation δ3=xp3, yp3, and θp3 associated with the moving direction position p3 read by the linear encoder 72, and an imaged positional deviation δ4=xp4, yp4, and θp4 associated with the moving direction position p4 from the imaged positional deviation information Hs.

Then, the error canceling arithmetic section 234B eliminates errors from work position information, obtained by the work position information obtaining section 230 and associated with the respective moving direction positions p2, p3, and p4, using the imaged positional deviations δ2, δ3, and δ4.

The errors may be eliminated from the work position information Jw, for example, by correcting the deviations γ2, γ3, and γ4, which are errors included in the work position information Jw illustrated in FIGS. 3B2, 3B3, and 3B4, to return the work position information Jw to the state of FIGS. 2B2, 2B3, and 2B4, and obtaining the position of the work 12 with respect to the table 14 as described above.

A method for returning the work position information Jw to the error-free state illustrated in FIGS. 2B2, 2B3, and 2B4 by correcting the displacements will be described. For example, when eliminating X component (xp2) and Y component (yp2) of the imaged positional deviation δ2(xp2, yp2, θp2) from γ2 which is the positional deviation, they may be subtracted directly.

When eliminating the θ component from the imaged positional deviation δ2(xp2, yp2, θp2), the following method may preferably be used.

FIG. 5 illustrates a method for eliminating the imaged positional deviation in the θ direction. Here, positional deviations in the X and Y directions are disregarded.

A rectangular shape 90A indicated by a dotted line represents an ideal position of the table 14 without displacement. The actual position of the table 14 is represented by a rectangular shape 90B indicated by a solid line, which is rotated in the θ direction by δθ.

A work reference mark 91 indicated by a dotted line represents an ideal position without displacement, and an imaging section (CCD) images the work reference mark 91 so as to be positioned in substantially the center of the field of the imaging section 226 in reliance on this design position.

Due to displacement of the work when placed, an original positional error of the reference mark when provided on the work, deformation of the work, or the like, however, the work reference mark 91 is actually imaged, by the imaging section 226, as a mark provided at the position indicated by the mark 92 (a position different from the ideal position).

When correcting a positional deviation δθ in the rotational direction from the imaged work reference mark position, if a correction value is obtained at the ideal position (Xd, Yd) of the work reference mark, the correction value is (Δx, Δy) in FIG. 5, and the corrected position of the work reference mark 91 is the position indicated by the mark 93.

In the mean time, the correction value at the actually imaged mark position (Xm, Ym) is (Δx′, Δy′) in FIG. 5, and the corrected position of the work reference mark 91 is the position indicated by the mark 94, so that the rotation δθ of the table 14 may be corrected accurately.

As described above, by obtaining an amount of correction based on mark position information actually imaged, an amount of correction error may be reduced even when the reference mark is deviated largely from the design value (ideal value).

Through the method described above, errors due to displacement of the table 14 may be eliminated from the work position information Jw. That is, corrected work position information JJw may be obtained by the work position obtaining arithmetic section 234.

### [Mechanical Correction Method]

A mechanical correction method will now be described.

When each of the reference marks is imaged, the work position obtaining control section 242 controls at least either one of the first and second work position obtaining moving sections 238A, 238B such that the imaged positional deviations δ2, δ3, and δ4 obtained from the imaged positional deviation information Hs in association with the moving direction positions p2, p3, and p4 are cancelled, so that the work position information Jw obtained by the work position information obtaining section 230 is made free of errors. That is, the corrected work position information JJw may be obtained by the work position information obtaining section 230.

The corrected work position information JJw obtained through the data correction method or mechanical correction method is stored in the work position information storage section 244.

When obtaining the corrected work position information JJw through the data correction method, a changeover switch 248 shown in FIG. 1 is switched off, and the corrected work position information JJw, not the work position information Jw, is transferred to the work position information storage section 244 and stored therein.

When obtaining the corrected work position information JJw through the mechanical correction method, the changeover switch is switched on, and the corrected work position information JJw obtained by the work position information obtaining section 230 is transferred to the work position information storage section 244 and stored therein.

It is noted that the corner sections of the table and work may also be used as the table reference mark and work reference mark respectively.

It is also noted that either one of the two correction methods or a combination thereof may be employed for the correction of imaged positional deviations.

An arrangement may be adopted in which the work position information obtaining apparatus described above includes a reference scale Sk, which is the imaged positional deviation measuring means for measuring imaged positional deviations, and while the table 14 is reciprocally moved repeatedly by the moving means, the work position obtaining arithmetic section 234 performs an arithmetic operation for eliminating the error using the imaged positional deviation measured by the reference scale Sk at a time in one or more previous reciprocal movement of the table 14 driven by the moving section 20.

Further, an arrangement may be adopted in which the work position information obtaining apparatus described above includes a reference scale Sk, which is the imaged positional deviation measuring means for measuring an imaged positional deviation, and while the table 14 is reciprocally moved repeatedly by the moving means, the work position obtaining control section 242 controls work position obtaining moving sections 238A, 238B using the imaged positional deviation measured with the reference scale Sk at one or more previous reciprocal movement of the table 14 driven by the moving section 20.

Still further, the work position obtaining storage section 232 may be a storage section that allows imaged positional deviation information stored therein to be updated every time the table 14 is moved reciprocally by the moving section 20.

Further, an arrangement may be adopted in which the work position information obtaining apparatus described above includes a reference scale Sk, which is the imaged positional deviation measuring means for measuring an imaged positional deviation, and the imaged positional deviation is measured using the reference scale Sk in an outward movement of the table 14 driven by the moving means 20, and the table reference mark 214 and work reference mark 212 are imaged by the imaging section 226 in a homeward movement of the table 14 driven by the moving means 20.

Description has been made of a case in which the table reference mark 214 and work reference mark 212 are imaged by the imaging means 226 at different timings to obtain the imaged table information and imaged work information as an embodiment of the work position information obtaining apparatus 200. It is noted that even when the table reference mark 214 and work reference mark 212 are imaged at the same timing by arranging imaging means 226 in the moving direction (Y direction in the drawings), an error due to displacement of the table 14 in the θ direction occurs. The error due to the displacement of the table 14 in the θ direction when the table reference mark 214 and work reference mark 212 are imaged at the same timing may be eliminated by the method described with reference to FIG. 5.

### [Operation of Image Plotting Apparatus 100]

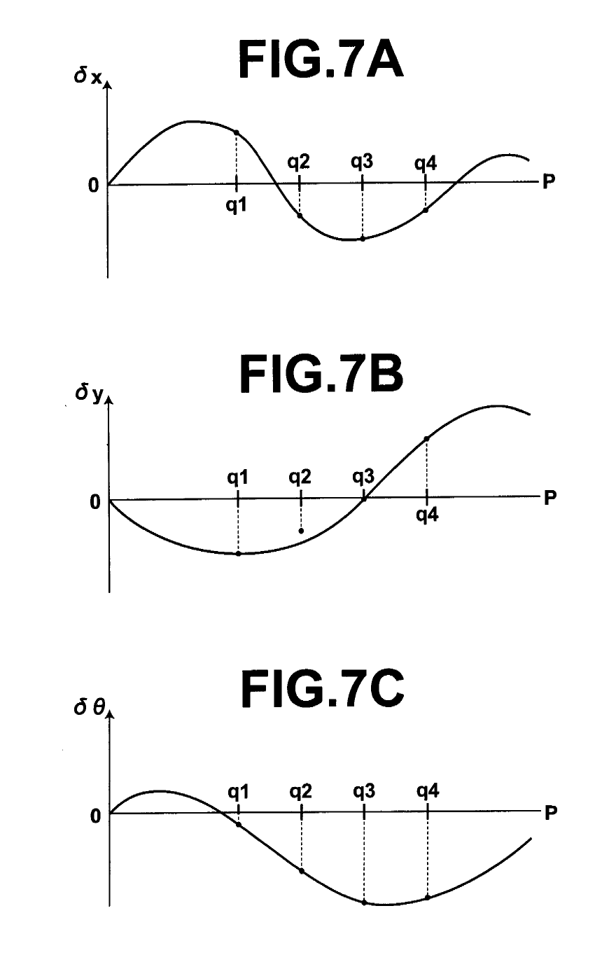

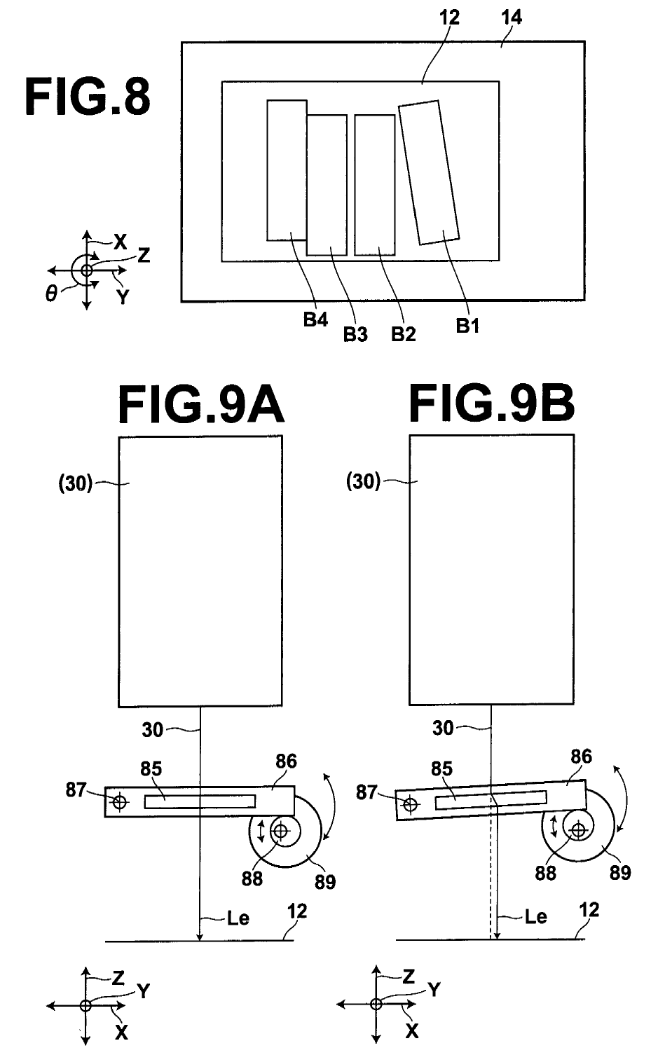

Next, an operation of the image plotting apparatus 100 will be described. FIG. 6 illustrates an image pattern when the table is moved without displacement. FIG. 7 illustrates the timings of plotting images and positional deviations of the table. FIG. 8 illustrates an image pattern plotted when the table is moved with displacement and the displacement are not corrected.

It is noted that the image pattern in FIG. 8 is illustrated schematically, and not correctly reflecting the state when the image pattern is plotted according to the positional deviations of the table in FIG. 7.

First, an operation for plotting an image pattern on the work 12 placed on the table 14 when the table 14 is moved by the moving means without displacement will be described.

Under control of the image plotting control section 28, while the table is moved by the moving section 20, partial image patterns, each corresponding to each moving direction position (q) obtained by the linear encoder 72, are sequentially plotted on the work 12 placed on the table 14 by the image plotting means 30, thereby an intended image pattern is plotted on the work 12. As illustrated in FIG. 7, partial image patterns B1, B2, B3, and B4 plotted at moving direction positions q1, q2, q3, and q4 are not displaced in the X, Y, and θ directions as illustrated in FIG. 6.

In contrast, when the table 14 is moved by the moving section 20 with displacement, the displacement occurs between the image plotting means 30 and table 14 by image plotting position deviations δ1(x1, y1, θ1), δ2(x2, y2, θ2), δ3(x3, y3, θ3), and δ4(x4, y4, θ4) at the moving direction positions q1, q2, q3, and q4 respectively. This causes each of the partial image patterns B1, B2, B3, and B4 to be plotted on the work in a displaced state as illustrated in FIG. 8.

In order to cause each partial image pattern to be plotted correctly by correcting the image plotting position deviations described above, the image plotting apparatus 100 includes three different correction methods: data correction, mechanical correction, and optical correction. The methods for correcting the positional deviations to correctly plot each partial image pattern may employ identical principles to those employed in the correction methods for correcting the positional deviations in the work position information obtaining apparatus 200 already described. For correcting the positional deviations described above, one of the three types of correction methods, or a combination of two or more methods may be employed.

### [Data Correction Method]

The image data correction section 78 obtains image plotting deviations from image plotting position deviation information Hb stored in the image plotting position deviation storage section 74 in association with the moving direction positions q1, q2, q3, and q4, and corrects original image data Go such that the image plotting position deviation is cancelled. The partial image patterns are plotted under control of the image plotting control section 28 using corrected image data G1 obtained by correcting the original image data Go in the image data correction section 78. This causes the displacement of each of the partial image patterns B1, B2, B3, and B4 to be corrected and each of the partial images may be plotted in the manner as illustrated in FIG. 6.

### [Mechanical Correction Method]

The image plotting correction control section 84 controls the first image plotting correction moving section 82A such that the image plotting position deviations obtained from the image plotting deviation information Hb stored in the image plotting position deviation storage section 74 in association with the moving direction positions q1, q2, q3, and q4 obtained by the linear encoder 72 are cancelled. In this case, the partial image patterns are plotted under control of the image plotting control section 28 using the original image data Go.

That is, the image plotting correction control section 84 controls the first image plotting correction moving section 82A to cause the table 14 and image plotting means 30 to be relatively moved such that the image plotting position deviations obtained from the image plotting deviation information Hb stored in the image plotting position deviation storage section 74 in association with the moving direction positions q1, q2, q3, and q4 obtained by the linear encoder 72 are cancelled. This causes the displacement of each of the partial image patterns B1, B2, B3, and B4 to be corrected and each of the partial image patterns may be plotted in the manner as illustrated in FIG. 6.

### [Optical Correction Method]

As in the mechanical correction method described above, the image plotting correction control section 84 controls the second image plotting correction moving section 82B such that the image plotting position deviations obtained from the image plotting deviation information Hb stored in the image plotting position deviation storage section 74 in association with the moving direction positions q1, q2, q3, and q4 obtained by the linear encoder 72 are cancelled, as in the mechanical correction. In this case, the partial image patterns are plotted under control of the image plotting control section 28 using the original image data Go.

The second image plotting correction moving section 82B includes: a transparent glass plate 85; a glass frame 86 for supporting the glass plate 85; a pin 87 for supporting the glass frame 86 at one end so as to be pivotable around the moving direction (arrow Y direction in the drawing); an eccentric cam 88 for moving the other end of the glass frame 86 in the direction (arrow Z direction in the drawing) orthogonal to the moving plane (X-Y plane); and an electric motor 89 for axially supporting and rotating the eccentric cam 88 as illustrated in FIGS. 9A, 9B.

The image plotting correction control section 84 controls the electric motor 89 to cause the eccentric cam 88 to be rotated. Thereby, the glass frame 86 is pivoted around the arrow Y direction in the drawing to move the position of the image plotting beam Le outputted from an image plotting head, which is the image plotting means 30, in the X direction in the drawing.

In the description above, the second image plotting correction moving section 82B moves the position of the image plotting beam Le outputted from an image plotting head, which is the image plotting means 30, in the X direction in the drawing. But, the position of the image plotting beam Le may be moved in the Y direction in the drawing by pivoting the glass frame 86 around the arrow X direction in the drawing using an identical mechanism to that described above.

### [Correction of Work Position With Respect To Table and of Table Displacement]

The image plotting apparatus 100 may correct both displacement of the work 12 with respect to the table 14, and the displacement of the table 14 being moved at the same time.

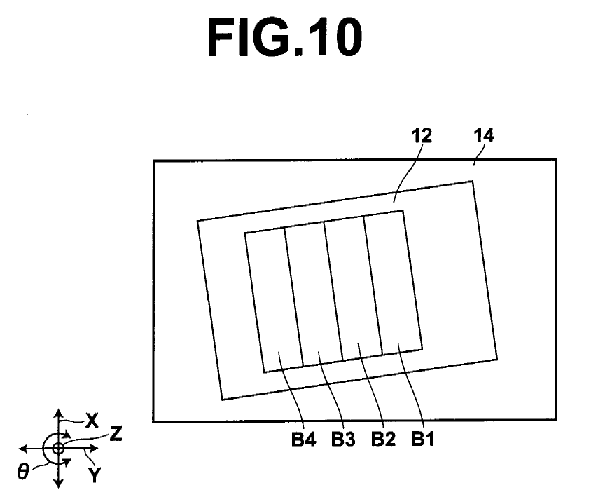

That is, displacement of the work 12 with respect to the table 14, and displacement of the table 14 may be corrected using both the corrected work position information JJw stored in the corrected work position information storage section 244 of the work position information obtaining apparatus 200, and image plotting position deviation stored in the image plotting position deviation storage section 74 of the image plotting apparatus 100. This allows each of the partial images B1, B2, B3, and B4 to be plotted at a predetermined correct position of the work 12 placed at a position deviated from a predetermined position on the table 14 as illustrated in FIG. 10.

Even in the case where the work is deformed, the use of the method described above allows an image pattern to be plotted on the work placed on the table 14 in optimum conditions according the deformation.

### [Data Correction Method]

As in the case where only the displacement of the table is corrected, the image data correction section 78 corrects the original image data Go stored in the image data memory 76 such that image plotting deviations obtained from the image plotting position deviation storage section 74 according to the moving direction positions q1, q2, q3, and q4, and amounts in the corrected work position information JJw obtained from the corrected work position information storage section 244 are cancelled. This causes the displacement of each of the partial image patterns B1, B2, B3, and B4 to be corrected and each of the partial images may be plotted in the manner as illustrated in FIG. 6.

### [Mechanical Correction Method]

The image plotting correction control section 84 controls the first image plotting correction moving section 82A such that the image plotting position deviations obtained in association with the moving direction positions q1, q2, q3, and q4 obtained by the linear encoder 72, and amounts in the corrected work position information JJw are cancelled. In this case, the partial image patterns are plotted under control of the image plotting control section 28 using the original image data Go.

### [Optical Correction Method]

As in the mechanical correction method described above, the image plotting correction control section 84 controls the second image plotting correction moving section 82B such that the image plotting position deviations obtained in association with the moving direction positions q1, q2, q3, and q4 obtained by the linear encoder 72, and amounts in the corrected work position information JJw are cancelled. In this case, the partial image patterns are plotted under control of the image plotting control section 28 using the original image data Go.

It is noted that any combination of the plurality of image plotting correction methods for plotting the image pattern correctly, and the plurality of work position obtaining methods for obtaining the work position on the table may be used. The combination is not limited to a single work position obtaining method and a single image plotting correction method, but a plurality of work position obtaining methods and a plurality of image plotting correction methods may be combined.

For example, a reference scale Sk, which acts both as the imaged positional deviation measuring means for measuring the imaged positional deviation and the image plotting position deviation measuring means for measuring the image plotting position deviation, is provided in the image plotting apparatus 100. Then, the position of the work 12 with respect to the table 14 is obtained by measuring a positional deviation that commonly indicates the imaged positional deviation and image plotting position deviation using the reference scale Sk, i.e., imaging the reference scale Sk by the imaging section 226, and imaging the table reference mark 214 and work reference mark 212 in an outward movement of the table 14. Thereafter, image plotting, which is variously corrected based on the positional deviation information and position information of the work 12 with respect to the table 14 obtained in the manner as described above, may be performed by the image plotting means 30 in a homeward movement of the table 14 driven by the moving section 20.

### [Detailed Description of Image Plotting Apparatus]

Hereinafter, the image plotting apparatus 100 according to the aforementioned embodiment will be described in detail.

As illustrated in FIG. 1, the image plotting apparatus 100 has a so-called flatbed configuration, and includes the plate-like table 14 for holding a work 12, which is a target material on which an image is to be plotted, thereon by suction. Two guides 20A extending along the moving direction of the table are provided on the upper surface of the thick plate-like mounting platform 18 which is supported by four legs 16. The table 14 is arranged such that its longitudinal direction is oriented to the moving direction thereof, and movably supported by the guides 20A to allow reciprocal movement. The image plotting apparatus 100 further includes the moving section 20 for moving the table 14 along the guides 20A.

An inverse U-shaped gate 22 striding over the moving path of the table 14 is provided at the central part of the mounting platform 18. Each of the ends of the inverse U-shaped gate 22 is disposed on each side of the mounting platform 18. An image plotting unit 24 having therein an image plotting head, constituting the image plotting means 30, is provided on one side of the gate 20, and the imaging section 226 having therein a plurality of CCD cameras (e.g. two) for detecting the front and rear edges of the work 12 and imaging the reference marks is provided on the other side. The image plotting unit 24 and imaging section 226 are fixedly attached to the gate 22 over the moving path of the table 14.

Inside of the image plotting unit 24 is a plurality of image plotting heads (e.g., 8) 30A, 30B, - - - , constituting the image plotting means 30, disposed in substantially a matrix form of “i” rows with “j” columns (e.g., 2 rows with 4 columns).

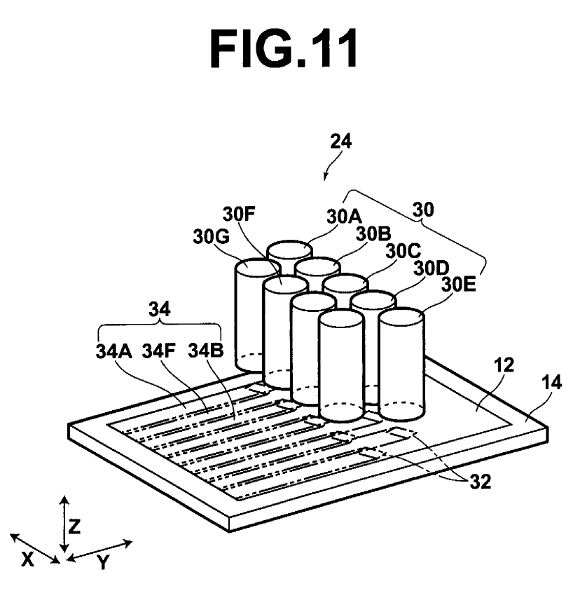

As illustrated in FIG. 11, image plotting areas 32A, 32B, - - - , (collectively referred to as “image plotting area 32”) of the image plotting heads 30A, 30B, - - - are, for example, rectangle with the long sides corresponding to the moving direction (arrow Y direction in the drawing). In this case, stripe-shaped plotted regions 34A, 34B, - - - , (collectively referred to as “plotted region 34”) are formed on the work 12 by the respective image plotting heads 30A, 30B, - - - .

Each of the image plotting heads 30A, 30B, - - - disposed in each row is displaced by a predetermined distance (product of the long side of the image plotting area multiplied by a natural number) in the column direction such that the stripe-shaped image plotted region 34 is disposed in an orthogonal direction (arrow X direction in the drawing) which is orthogonal to the moving direction without any gap between them. That is, the portion between the image plotting area 32A which is plotted by the image plotting head 30A and image plotting area 32B which is plotted by the image plotting head 30B may be the image plotting area 32F which is plotted by the image plotting head 30F.

### [Schematic Configuration of Image Plotting Head]

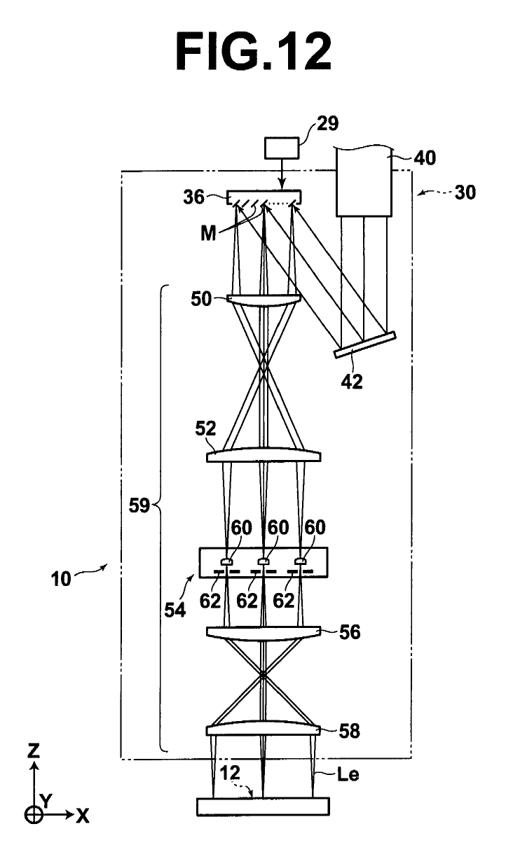

As illustrated in FIGS. 1 and 12, the image plotting means 30 spatially modulates light outputted from a light source 38, passed through an optical fiber 40, and outputted therefrom via a DMD (digital micromirror device) 36, a spatial light modulation device, which includes multitudes of micromirrors M, microscopic light modulation devices, arranged two-dimensionally, and focuses an image plotting beam Le, formed according to the light modulation state of each micromirror M, on the work 12, thereby forming an image pattern, such as a wiring pattern.

Each image plotting means 30 includes the digital micromirror device (DMD) 36 as a spatial light modulator for spatially modulating light beam outputted from the light source 38, passed through the optical fiber 40, and outputted therefrom. The DMD 36 is connected to a DMD controller 29 which includes a data processing section, a mirror drive control section, and the like.

The DMD controller 29 controls the angle of reflection surface of a micromirror of a DMD 36 to be controlled with respect to each of the image plotting heads 30A, 30B, - - - based on inputted image data.

As illustrated in FIG. 1, the bundled optical fiber 40, each fiber drawn out from the light source 38, is disposed on the light input side of the DMD 36 included in each of the image plotting heads 30A, 30B, - - - .

The light source 38 includes a plurality of light combining modules for combining laser beams outputted from a plurality of semiconductor laser chips and inputting to the optical fibers. The optical fibers extending from the respective light combining modules are combined light optical fibers for propagating the combined laser beams, and bundled together to form the bundled optical fiber 40.

Further, on the light input side of the DMD 36 of the image plotting means 30 is a mirror 42 for reflecting light outputted from the bundled optical fiber 40 toward the DMD 36.

Next, an imaging optical system 59 provided on the light output side of the DMD 36 of the image plotting means 30 will be described. For focusing an image from the light source on the work 12, the imaging optical system 59 includes: lens systems 50, 52, a microlens array 54, objective lens systems 56, 58 in this order along the light path from the DMD 36 to the work 12, as illustrated in FIG. 12.

The lens systems 50, 52 form a magnifying lens system, and magnify the area of an image plotting area 32 on the work 12 to a predetermined size.

As illustrated in FIG. 12, the microlens array 54 includes a plurality of microlenses 60 formed integrally, each corresponding to each micromirror M of the DMD 36 and disposed to pass through each corresponding pixel light beam transmitted through the lens systems 50, 52.

The microlens array 54 has a rectangular planar plate shape, and an aperture 62 is provided adjacent to each of the microlens 60. Each aperture 62 acts as an aperture stop disposed in one-on-one relationship with each microlens 60.

The objective lens systems 56, 58 form, for example, a non-magnifying optical system. The work 12 is placed at a position where the pixel light beam L is focused through the objective lens systems 56, 58.

The structure described above allows the image plotting beam Le, which is the image plotting means 30, outputted from the light source 38 may be focused on the work 12 to form an image pattern thereon.

### [Image Plotting Operation by Image Plotting Apparatus]

Next, an operation of the image plotting apparatus 100 for plotting an image pattern on a work 12 will be described.

The table 14 with the work 12 placed thereon is moved along the guides 20A at a constant speed from the upstream to down stream in the moving direction. When the table 14 passes under the gate 22, the fore edge of the work 12 is detected by the imaging section 226 attached to the gate 22, and thereby image data reading for a plurality of lines at a time is initiated.

Each of the micromirrors of the DMD of each of the image plotting heads 30A, 30B, - - - are on-off controlled by the mirror drive control section of the DMD controller 29.

When a light beam outputted from the optical fiber 40 and reflected by the mirror 42 is irradiated on the DMD 36, the laser beam reflected by an on-state micromirror is focused on the image plotting surface of the work 12 through the lens system, including a corresponding microlens 60 of the microlens array 54. In this way, the pixel light beam L is outputted from the DMD 36 and passed through the microlens array 54, thereby image plotting is performed on the work 12 on the basis of unit (image plotting area) of pixels substantially equal to that of the DMD 36.

By moving the table 14 with the work 12 placed thereon at a constant speed, the image plotting unit 24 is relatively moved in the direction opposite to the moving direction, thereby the stripe-shaped plotted region 34 is formed by each of the image plotting heads 30A, 30B, - - - .

That is, by irradiating the image plotting beam Le, generated by modulating the DMD 36 according to an image pattern to be plotted, on the work 12, the image pattern is plotted on the work 12.

When image plotting by the image plotting unit 24 is completed and the rear end of the work 12 is detected by the imaging section 226, the table 14 is returned to the original position at the uppermost stream in the moving direction along the guides 20A. Thereafter, image plotting may be repeated by moving the table 14 again from the upstream to downstream in the moving direction at a constant speed along the guides 20A. That is, image plotting on the work 12 by the image plotting unit 24 may be performed every time the table 14 is reciprocally moved by the moving section 20.

### [Generation of DMD Reset Signal]

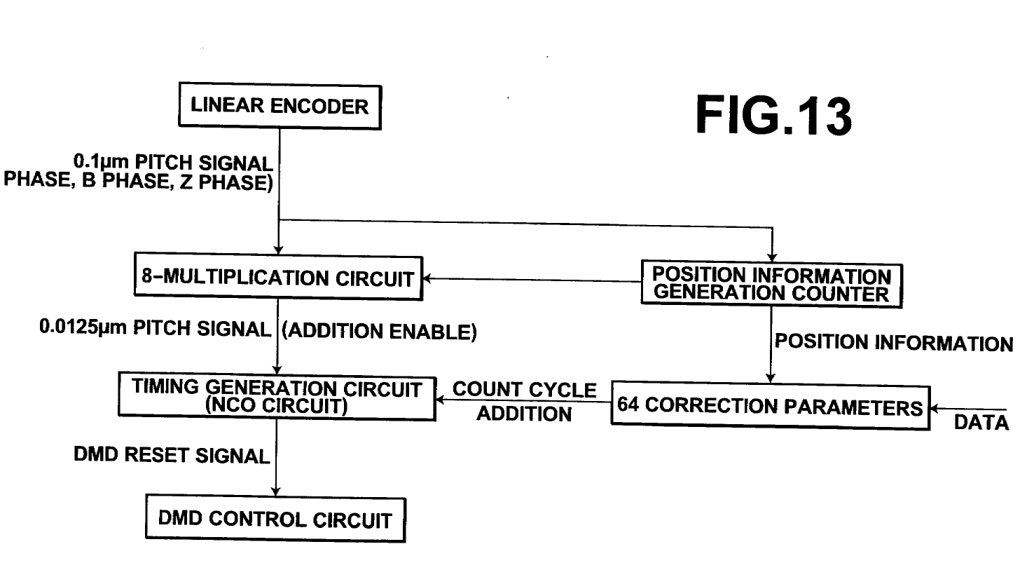

FIG. 13 is a block diagram, illustrating a processing method of moving direction positions of the table 14 obtained by the linear encoder 72. A signal with a pitch of 0.1 μm outputted from the linear encoder 72 according to the movement of the table 14 is converted to a signal with a pitch of 0.0125 μm through an 8-multiplication circuit. This signal is used by the DMD controller 29 to control the DMD 36. But a positional deviation of the table 14 occurs in the moving direction while it is moved. Therefore, the image plotting region is divided into, for example, 64 regions (e.g., 10 mm intervals), and a reset interval for correcting the positional deviation is adjusted for each region. The reset cycle is generated by an NCO (numerical controlled oscillator) circuit. This allows surplus of the pulse to be allocated equally, and the reset interval may be made uniform. The signal generated in the NCO circuit is used as a DMD reset signal and inputted to the DMD control circuit.

1-14. (canceled)

15. A work position information obtaining method, comprising the steps of:
moving a table with a work placed thereon relative to an imaging means for imaging over the surface of the table;
obtaining imaged table information and imaged work information by imaging a table reference mark provided on the table being moved and a work reference mark provided on the work placed on the table, and obtaining moving direction position information representing moving direction positions of the table when the table reference mark and work reference mark are imaged; and
obtaining work position information representing a position of the work with respect to the table based on the imaged table information, imaged work information, and moving direction position information, wherein:
imaged positional deviation information representing an imaged positional deviation, which indicates displacement of the table that occurs when the table is moved relative to the imaging means, in association with each of the moving direction positions of the table is obtained in advance; and
an error included in the work position information arising from the difference between each imaged positional deviation is eliminated using the imaged positional deviation corresponding to the moving direction position of the table at the time of imaging the table reference mark obtained from the imaged positional deviation information, and the imaged positional deviation corresponding to the moving direction position of the table at the time of imaging the work reference mark obtained from the imaged positional deviation information.

16. A work position information obtaining apparatus, comprising:
a table on which a work is placed;
an imaging means for imaging over the surface of the table;
a moving means for moving the table relative to the imaging means;
a moving direction position information obtaining means for obtaining moving direction position information representing a moving direction position of the table with respect to the imaging means;
a work position information obtaining means for obtaining work position information representing a position of the work with respect to the table based on imaged table information and imaged work information obtained by imaging a table reference mark provided on the table being relatively moved and a work reference mark provided on the work placed on the table, and the moving direction position information of the table at the time of imaging the table reference mark and at the time of imaging the work reference mark obtained by the moving direction position information obtaining means;
a work position obtaining storage means for storing imaged positional deviation information, obtained in advance, representing a positional deviation, which indicates displacement of the table that occurs when the table is moved relative to the imaging means, in association with each of the moving direction positions of the table; and
a work position obtaining arithmetic means for performing an arithmetic operation for eliminating an error included in the work position information arising from the difference between each imaged positional deviation using the imaged positional deviation corresponding to the moving direction position of the table at the time of imaging the table reference mark obtained from the imaged positional deviation information, and the imaged positional deviation corresponding to the moving direction position of the table at the time of imaging the work reference mark obtained from the imaged positional deviation information.

17. The work position information obtaining apparatus of claim 16, wherein the work position obtaining arithmetic means is a means for performing the arithmetic operation for calculating the error using the imaged information at the time of imaging the table reference mark and the imaged information at the time of imaging the work reference mark.

18. The work position information obtaining apparatus of claim 16, wherein the imaged positional deviation information is information representing an imaged positional deviation in the moving direction, an imaged positional deviation in an orthogonal moving direction which is orthogonal to the moving direction and parallel to a moving plane, and an imaged positional deviation in a rotational direction around an orthogonal moving plane direction which is orthogonal to the moving plane.

19. The work position information obtaining apparatus of claim 17, wherein the imaged positional deviation information is information representing an imaged positional deviation in the moving direction, an imaged positional deviation in an orthogonal moving direction which is orthogonal to the moving direction and parallel to a moving plane, and an imaged positional deviation in a rotational direction around an orthogonal moving plane direction which is orthogonal to the moving plane.

20. The work position information obtaining apparatus of claims 16, wherein:
the apparatus comprises an imaged positional deviation measuring means for measuring the imaged positional deviation; and
the work position obtaining arithmetic means is a means for performing the arithmetic operation for eliminating the error using the imaged positional deviation measured by the imaged positional deviation measuring means at a time in one or more previous reciprocal movement of the table while the table is reciprocally moved repeatedly by the moving means.

21. The work position information obtaining apparatus of claim 17, wherein:
the apparatus comprises an imaged positional deviation measuring means for measuring the imaged positional deviation, and
the work position obtaining arithmetic means is a means for performing the arithmetic operation for eliminating the error using the imaged positional deviation measured by the imaged positional deviation measuring means at a time in one or more previous reciprocal movement of the table while the table is reciprocally moved repeatedly by the moving means.

22. A work position information obtaining method, comprising the steps of:
moving a table with a work placed thereon relative to an imaging means for imaging over the surface of the table;
obtaining imaged table information and imaged work information by imaging a table reference mark provided on the table being moved and a work reference mark provided on the work placed on the table, and obtaining moving direction position information representing moving direction positions of the table when the table reference mark and work reference mark are imaged; and
obtaining work position information representing a position of the work with respect to the table based on the imaged table information, imaged work information, and moving direction position information, wherein:
imaged positional deviation information representing an imaged positional deviation, which indicates displacement of the table that occurs when the table is moved relative to the imaging means, in association with each of the moving direction positions of the table is obtained in advance; and
the work position information is made free of an error arising from the displacement of the table by relatively moving the table and imaging means such that the imaged positional deviation corresponding to the moving direction position of the table at the time of imaging the table reference mark obtained from the imaged positional deviation information is cancelled when imaging the table reference mark, and relatively moving the table and imaging means such that the imaged positional deviation corresponding to the moving direction position of the table at the time of imaging the work reference mark obtained from the imaged positional deviation information is cancelled when imaging the work reference mark.

23. A work position information obtaining apparatus, comprising:
a table on which a work is placed;
an imaging means for imaging over the surface of the table;
a moving means for moving the table relative to the imaging means;
a moving direction position information obtaining means for obtaining moving direction position information representing a moving direction position of the table with respect to the imaging means;
a work position information obtaining means for obtaining work position information representing a position of the work with respect to the table based on imaged table information and imaged work information obtained by imaging a table reference mark provided on the table being relatively moved and a work reference mark provided on the work placed on the table, and the moving direction position information of the table at the time of imaging the table reference mark and at the time of imaging the work reference mark obtained by the moving direction position information obtaining means;
a work position obtaining storage means for storing imaged positional deviation information, obtained in advance, representing a positional deviation, which indicates displacement of the table that occurs when the table is moved relative to the imaging means, in association with each of the moving direction positions of the table;
a work position obtaining moving means for relatively moving the table and imaging means; and
a work position obtaining control means for controlling the work position obtaining moving means to cause the table and imaging means to be relatively moved such that the imaged positional deviation corresponding to the moving direction position of the table at the time of imaging the table reference mark obtained from the imaged positional deviation information is cancelled when imaging the table reference mark, and to cause the table and imaging means to be relatively moved such that the imaged positional deviation corresponding to the moving direction position of the table at the time of imaging the work reference mark obtained from the imaged positional deviation information is cancelled when imaging the work reference mark, wherein
the work position information obtained by the work position information obtaining means is made free of an error arising from the displacement of the table.

24. The work position information obtaining apparatus of claim 23, wherein the work position obtaining control means is a means for causing only the imaging means to be moved.

25. The work position information obtaining apparatus of claim 23, wherein the work position obtaining control means is a means for causing only the table to be moved.

26. The work position information obtaining apparatus of claim 23, wherein the imaged positional deviation information is information representing an imaged positional deviation in the moving direction, an imaged positional deviation in an orthogonal moving direction which is orthogonal to the moving direction and parallel to a moving plane, and an imaged positional deviation in a rotational direction around an orthogonal moving plane direction which is orthogonal to the moving plane.

27. The work position information obtaining apparatus of claim 23, wherein:
the apparatus comprises an imaged positional deviation measuring means for measuring the imaged positional deviation, and
the work position obtaining control means is a means for controlling the work position obtaining moving means using the imaged positional deviation measured by the imaged positional deviation measuring means at a time in one or more previous reciprocal movement of the table while the table is reciprocally moved repeatedly by the moving means.

28. The work position information obtaining apparatus of claim 26, wherein:
the apparatus comprises an imaged positional deviation measuring means for measuring the imaged positional deviation, and
the work position obtaining control means is a means for controlling the work position obtaining moving means using the imaged positional deviation measured by the imaged positional deviation measuring means at a time in one or more previous reciprocal movement of the table while the table is reciprocally moved repeatedly by the moving means.

29. The work position information obtaining apparatus of claim 16, wherein the work position obtaining storage means is a means that allows the imaged positional deviation information stored therein to be updated every time the table is reciprocally moved by the moving means.

30. The work position information obtaining apparatus of claim 23, wherein the work position obtaining storage means is a means that allows the imaged positional deviation information stored therein to be updated every time the table is reciprocally moved by the moving means.

31. The work position information obtaining apparatus of claim 16, wherein:
the apparatus comprises an imaged positional deviation measuring means for measuring the imaged positional deviation, and
an imaged positional deviation is measured by the imaged positional deviation measuring means in an outward movement of the table driven by the moving means, and table reference mark and work reference mark are imaged by the imaging means in a homeward movement of the table driven by the moving means.

32. The work position information obtaining apparatus of claim 23, wherein:
the apparatus comprises an imaged positional deviation measuring means for measuring the imaged positional deviation, and
an imaged positional deviation is measured by the imaged positional deviation measuring means in an outward movement of the table driven by the moving means, and table reference mark and work reference mark are imaged by the imaging means in a homeward movement of the table driven by the moving means.

33. The work position information obtaining apparatus of claim 16, wherein the imaging means is a means for obtaining the imaged table information and imaged work information by imaging the table reference mark provided on the table being moved and work reference mark provided on the work placed on the table at different timings with each other.

34. The work position information obtaining apparatus of claim 23, wherein the imaging means is a means for obtaining the imaged table information and imaged work information by imaging the table reference mark provided on the table being moved and work reference mark provided on the work placed on the table at different timings with each other.
